(19) United States
(12) Patent Application Publication
(10) Pub. No.: US 2024/0146309 A1
(43) Pub. Date: May 2, 2024

(54) OSCILLATOR CIRCUIT HAVING TEMPERATURE COMPENSATION BASED ON RESONATOR GROUP-DELAY ANALYSIS

(71) Applicant: TEXAS INSTRUMENTS INCORPORATED, Dallas, TX (US)

(72) Inventors: Jeronimo SEGOVIA-FERNANDEZ, San Jose, CA (US); Ali DJABBARI, Saratoga, CA (US); Peter SMEYS, San Jose, CA (US)

(21) Appl. No.: 18/050,451

(22) Filed: Oct. 27, 2022

(51) Int. Cl. H03L 1/02; H03B 5/04

(52) U.S. Cl. CPC H03L 1/027; H03B 5/04; H03L 7/099

(57) ABSTRACT

A circuit includes: a first resonator; a temperature compensation circuit including a resonator group-delay analyzer and a second resonator; oscillator control circuitry; and a controller. The resonator group-delay analyzer is configured to determine a group-delay parameter responsive to operations of the second resonator. The controller is configured to provide a control signal responsive to the group-delay parameter. The oscillator control circuitry is configured to adjust a frequency of an output signal of the oscillator control circuitry responsive to the control signal.

### BACKGROUND

Improvements in semiconductor fabrication allow engineers to integrate electroacoustic resonators with complementary metal oxide semiconductor (CMOS) circuits and build high-end performing oscillator circuits of small form factor. By increasing the resonance frequency of the electroacoustic resonator over the oscillation frequency, the oscillator short-term instability becomes less dependent on the resonator quality factor. Moreover, the integration with CMOS allows circuit designers to implement active compensation circuits in close proximity with the electroacoustic resonator, achieving better frequency stabilization. One source of frequency instability is temperature. Conventional temperature compensation circuits are based on: 1) frequency detection; or 2) constant resistance. Temperature compensation circuits based on frequency detection measure the frequency difference given between two oscillators whose electroacoustic resonators have different temperature coefficients of frequency (TCF). Temperature compensation circuits based on constant resistance measure the variation of voltage across a resistor as a function of temperature. The frequency detection approach generally achieves higher frequency stability, compared to the constant resistance approach, but requires higher power consumption and a longer response time. The constant resistance approach generally consumes less power, compared to the frequency detection approach, but exhibits a higher measurement error. Efforts to improve oscillator frequency stability while reducing system complexity and power consumption are ongoing.

### SUMMARY

In an example embodiments, a circuit comprises: a first resonator having first and second terminals; a temperature compensation circuit including a resonator group-delay analyzer and a second resonator, the resonator group-delay analyzer having first and second analyzer inputs and an analyzer output, the second resonator having third and fourth terminals, the fourth terminal coupled to the first analyzer input; oscillator control circuitry having a first control input, first and second outputs, and an oscillator output, the first output coupled to the first terminal, and the second output coupled to the second terminal; and a controller having a second control input and a control output, the second control input coupled to the analyzer output, and the control output coupled to first control input. The controller is configured to provide a control signal at the control output responsive to a group-delay parameter received at the second control input. The oscillator control circuitry is configured to adjust a frequency of an output signal at the oscillator output responsive to the control signal.

In another example embodiment, an oscillator circuit comprises: a first resonator; a temperature compensation circuit including a second resonator, the temperature compensation circuit configured to determine a group-delay amplitude responsive to operations of the second resonator; oscillator control circuitry coupled to the first resonator and configured to adjust a frequency of an output signal of the oscillator circuit responsive to a control signal; and a controller coupled to the oscillator control circuitry and the temperature compensation circuit. The controller is configured to: receive the group-delay amplitude from the temperature compensation circuit; and provide the control signal to the oscillator control circuitry responsive to the group-delay amplitude.

### BRIEF DESCRIPTION OF THE DRAWINGS

FIG. 1 is a block diagram showing a circuit in accordance with an example embodiment.

FIG. 2 is a schematic diagram showing an oscillator circuit in accordance with an example embodiment.

FIG. 3 is a graph showing frequency variation as a function of temperature for a first and second resonators in accordance with an example embodiment.

FIG. 4 is a schematic diagram showing an equivalent circuit related to a 2-port electroacoustic resonator in accordance with an example embodiment.

FIGS. 5A and 5B are graphs showing resonator parameters as a function of frequency in accordance with an example embodiment.

FIG. 6 is a graph 600 showing group-delay of an uncompensated resonator measured at the oscillator frequency (f₀) for different temperatures.

FIG. 7 is a graph showing group-delay amplitude as a function of temperature.

FIG. 8 is a flowchart showing an output frequency control method for an oscillator circuit in accordance with an example embodiment.

### DETAILED DESCRIPTION

The same reference numbers or other reference designators are used in the drawings to designate the same or similar (either by function and/or structure) features.

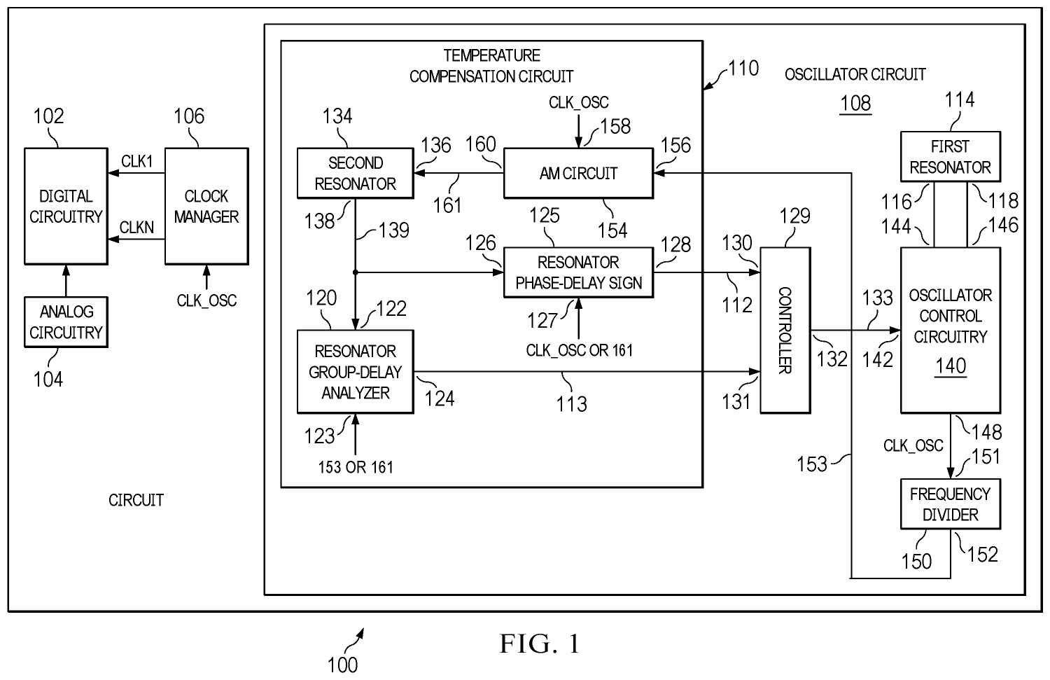

FIG. 1 is a block diagram showing a circuit 100 in accordance with an example embodiment. In the example of FIG. 1, the circuit 100 includes digital circuitry 102 and a clock manager 106 coupled to the digital circuitry 102. The circuit 100 also includes analog circuitry 104 coupled to the digital circuitry 102. In some example embodiments, the analog circuitry 104 may include an analog communication interface, an antenna interface, and/or analog sensors. The analog circuitry 104 may also include analog-to-digital converters (ADCs) as needed and/or other digitizer circuitry. The digital circuitry 102 may include a microprocessor, memory, a field-programmable grid array (FPGA), and/or other programmable circuits.

In the example of FIG. 1, the clock manager 106 receives a clock signal (CLK_OSC), where CLK_OSC is the output signal from an oscillator circuit 108. In operation, the clock manager 106 is configured to generate various clock signals (e.g., CLK1 to CLKN) for the digital circuitry 102 based on CLK_OSC. In different example embodiments, the frequencies and/or phases of CLK1 to CLKN may vary.

To provide CLK_OSC, the oscillator circuit 108 includes a first resonator 114, oscillator control circuitry 140, a divider circuit 150, a controller 129, and a temperature compensation circuit 110. The temperature compensation circuit 110 includes a second resonator 134, a resonator group-delay analyzer 120, a resonator phase-delay sign circuit 125, and an amplitude modulation (AM) circuit 154.

In the example of FIG. 1, the first resonator 114 has a first terminal 116 and a second terminal 118. The oscillator control circuitry 140 has a first control input 142, a first output 144, a second output 146, and an oscillator output 148. The divider circuit 150 has a divider input 151 and a divider output 152. The second resonator 134 has a third terminal 136 and a fourth terminal 138. The resonator group-delay analyzer 120 has a first analyzer input 122, a second analyzer input 123, and an analyzer output 124. The resonator phase-delay sign circuit 125 has a first sign circuit input 126, a second sign circuit input 127, and a sign circuit output 128. The amplitude modulation (AM) circuit 154 has a first modulation input 156, a second modulation input 158, and a modulation output 160. The controller 129 includes a second control input 130, a third control input 131 and a control output 132.

As shown, the first terminal 116 of the first resonator 114 is coupled to the first output 144 of the oscillator control circuitry 140. The second terminal 118 of the first resonator 114 is coupled to the second output 146 of the oscillator control circuitry 140. The first control input 142 of the oscillator control circuitry 140 is coupled to the control output 132 of the controller 129 and receives a control signal 133. The oscillator output 148 of the oscillator control circuitry 140 is coupled to the divider input 151 and the second modulation input 158, each receiving CLK_OSC from the oscillator output 148. The oscillator output 148 may also be coupled to the second sign circuit input 127, which receives CLK_OSC in some example embodiments. The divider output 152 is coupled to the first modulation input 156, which receives the divider results 153. The divider output 152 may also be coupled to the second analyzer input 123, which may receive the divider results 153 in some example embodiments. The modulation output 160 is coupled to the third terminal 136 of the second resonator 134, which receives the modulation results 161. The fourth terminal 138 of the second resonator 134 is coupled to the first analyzer input 122 and the first sign circuit input 126, each receiving delayed modulation results 139 based on the operations of the second resonator 134. As previously noted, the second analyzer input may be coupled to the divider output 152 and may receive the divider results 153. In other example embodiments, the second analyzer input 123 is coupled to the modulation output 160 and receives the modulation results. The analyzer output 124 is coupled to the third control input 131 of the controller 129. In some example embodiments, the second sign circuit input 127 is coupled to the oscillator output 148 and receives CLK_OSC. In other example embodiments, the second sign circuit input 127 is coupled to the modulation output 160 and receives the modulation results 161. The sign circuit output 128 is coupled to the second control input 130 of the controller 129. The control output 132 is coupled to the first control input 142 of the oscillator control circuitry 140.

In operation, the resonator group-delay analyzer 120 is configured to provide a group-delay amplitude 112 to the analyzer output 124 responsive to: divider results 153 (from the divider output 152) or the modulation results 161 (from the modulation output 160) received at the second analyzer input 123; and the operations of the second resonator 134. The resonator phase-delay sign circuit 125 is configured to provide a phase-delay sign 113 at the sign circuit output 128 responsive to: CLK_OSC or the modulation results 161 received at the second sign circuit input 127; and the operations of the second resonator 134. If the modulation results 161 (instead of CLK_OSC) are received at the second sign circuit input 127, the time delay introduced by intermediate components is not present, which reduces the group delay error. If CLK_OSC is used, increments of phase delay may be considered, which allows the phase delay introduced by intermediate components to be estimated. The estimated phase delay due to intermediate components may then be used to reduce the group delay error.

The operations of the second resonator 134 are based on modulation results 161 provided by the AM circuit 154. Specifically, the AM circuit 154 is configured to provide the modulation results 161 at the modulation output 160 responsive to the divider results 153 received at the first modulation input 156 and CLK_OSC received at the second modulation input 158. The controller 129 is configured to provide a control signal 133 at the control output 132 responsive to the phase-delay sign 113 and the group-delay amplitude 112. The oscillator control circuitry 140 is configured to adjust a frequency of CLK_OSC responsive to the control signal 133. With the temperature-compensation circuit 110, frequency variation of the first resonator 114 due to temperature is accounted for, which improves accuracy of CLK_OSC relative to a target output frequency.

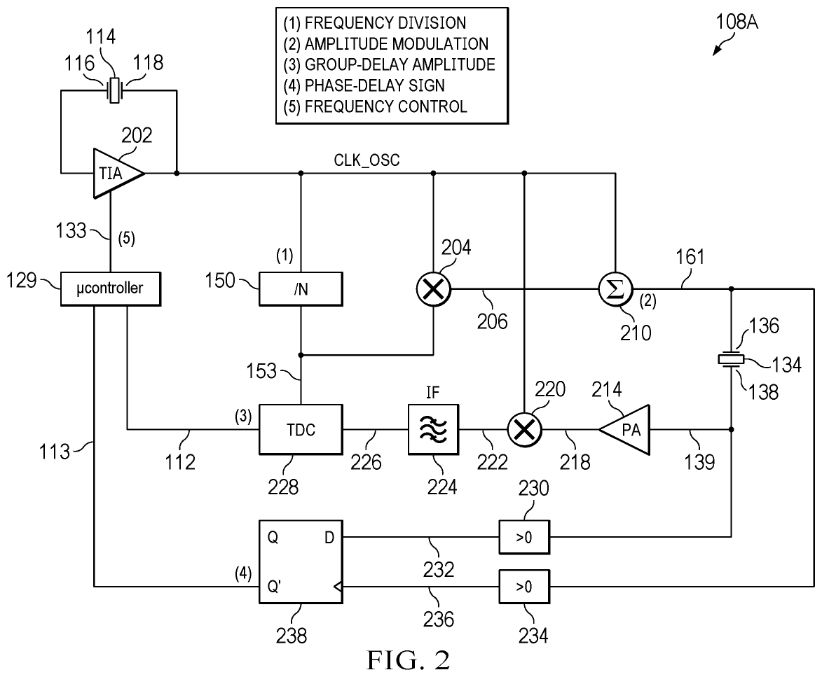

FIG. 2 is a schematic diagram showing an oscillator circuit 108A (an example of the oscillator circuit 108 in FIG. 1) in accordance with an example embodiment. In the example of FIG. 2, the oscillator circuit 108A is configured to perform the following operations labeled as: (1) frequency division; (2) amplitude modulation; (3) group-delay amplitude; (4) phase-delay sign; and (5) frequency control. The frequency division operations of the oscillator circuit 108A divide the CLK_OSC frequency. The amplitude modulation operations of the oscillator circuit 108A adjust the amplitude of CLK_OSC at a rate that depends on the modulation signal generated by frequency division. The group-delay amplitude operations of the oscillator circuit 108A determine the group-delay amplitude 112 responsive to operations of the second resonator 134. The phase-delay sign operations of the oscillator circuit 108A determine the phase-delay sign 113 responsive to operations of the second resonator 134. The frequency control operations of the oscillator circuit 108A determine the control signal 133 responsive to the group-delay amplitude 112 and the phase-delay sign 113. The control signal 133 is used to adjust the frequency of CLK_OSC.

In the example of FIG. 2, the oscillator circuit 108A includes the first resonator 114 in a feedback loop of a transimpedance amplifier (TIA) 202. Specifically, the first terminal 116 of the first resonator 114 is coupled to the input of the TIA 202, while the second terminal 118 of the first resonator 114 is coupled to the output of the TIA 202. In the example of FIG. 2, the TIA 202 is an example of oscillator control circuitry such as the oscillator control circuitry 140 of FIG. 1.

To provide temperature compensation for CLK_OSC, the oscillator circuit 108A includes the controller 129, which is a microcontroller in the example of FIG. 2. In operation, the controller 129 is configured to provide the control signal 133 to the TIA 202 responsive to the group-delay amplitude 112 and the phase-delay sign 113. The TIA 202 is configured to adjust the frequency of CLK_OSC response to the control signal 133. In different scenarios, the TIA 202 may adjust the frequency of CLK_OSC up or down responsive to the control signal 133.

To determine the group-delay amplitude 112, the oscillator circuit 108A uses the second resonator 134, the divider circuit 150, a first mixer circuit 204, a summation circuit 210, an amplifier circuit 214, a second mixer circuit 220, a filter circuit 224, and a time-to-digital converter (TDC) circuit 228. As shown, the divider circuit 150 is configured to receive CLK_OSC and provide the divider results 153 based on CLK_OSC. The first mixer circuit 204 is configured to provide first mixer results 206 based on the divider results 153 and CLK_OSC. The summation circuit 210 is configured to provide the modulation results 161 based on the first mixer results 206 and CLK_OSC. The modulation results 161 result in the delayed modulation results 139 based on operations of the second resonator 134. The second mixer circuit 220 is configured to provide second mixer results 222 responsive to the delayed modulation results 139 (optionally amplified by the amplifier circuit 214) and CLK_OSC. The filter circuit 224 is configured to provide filter results 226 (e.g., only the divider results 153 are included in the filter results 226) responsive to the second mixer results 222. The TDC circuit 228 is configured to provide the group-delay amplitude 112 responsive to the filter results 226 and the divider results 153.

To determine the group-delay amplitude 112, the oscillator circuit 108A uses a first 1-bit ADC 230, a second 1-bit ADC 234, and a D flip-flop 238. The first 1-bit ADC 230 is configured to provide a first ADC result 232 responsive to the delayed modulation results 139. In some example embodiments, the first ADC result 232 is: a logical “1” when the delayed modulation results 139 is greater than 0; and a logical “0” when the delayed modulation results 139 is not greater than 0. The second 1-bit ADC 234 is configured to provide a second ADC result 236 responsive to the delayed modulation results 139. In some example embodiments, the second ADC result 236 is: a logical “1” when the delayed modulation results 139 is greater than 0; and a logical “0” when the delayed modulation results 139 is not greater than 0. The D flip-flop 238 is configured to provide the phase-delay sign 113 responsive to the first ADC result 232 and the second ADC result 236. In some example embodiments, the first ADC result 232 is received at a D input of the D flip-flop 238, the second ADC result 236 is received at a reset input of the D flip-flop 238, and the phase-delay sign 113 is output from the Q′ output of the D flip-flop 238.

In some example embodiments, an oscillator circuit (e.g., the oscillator circuit 108 in FIG. 1, or the oscillator circuit 108A in FIG. 2) includes a first resonator (e.g., the first resonator 114 in FIGS. 1 and 2); and a temperature compensation circuit (e.g., the temperature compensation circuit 110 in FIG. 1, or related components in FIG. 2). In some example embodiments the temperature compensation circuit includes a second resonator (e.g., the second resonator 134 in FIGS. 1 and 2). The temperature compensation circuit configured to determine a group-delay amplitude (e.g., the group-delay amplitude 112 in FIGS. 1 and 2) responsive to operations of the second resonator. The oscillator circuit also includes oscillator control circuitry (e.g., the oscillator control circuitry 140 in FIG. 1, or the TIA 202 in FIG. 2) coupled to the first resonator and configured to adjust a frequency of an output signal (e.g., CLK_OSC) of the oscillator circuit responsive to a control signal (e.g., the control signal 133 in FIGS. 1 and 2). The oscillator circuit also includes a controller (e.g., the controller 129 in FIGS. 1 and 2) coupled to the oscillator control circuitry and the temperature compensation circuit. The controller is configured to: receive the group-delay amplitude from the temperature compensation circuit; and provide the control signal to the oscillator control circuitry responsive to the group-delay amplitude.

In some example embodiments, the temperature compensation circuit is configured to determine a phase-delay sign (e.g., the phase-delay sign 113 in FIGS. 1 and 2) responsive to delayed modulation results (e.g., the delayed modulation results 139 in FIGS. 1 and 2) based on the operations of the second resonator. In some example embodiments, the controller is configured to: determine a temperature based on the group-delay amplitude and the phase-delay sign; and provide the control signal responsive to the determined temperature. In some example embodiments, the controller is configured to determine the temperature based on a Lorentzian function having coefficients that vary as a function of a maximum group-delay amplitude, a full-width half maximum of the group-delay amplitude, the phase-delay sign, and a setpoint temperature.

In some example embodiments, the oscillator circuit includes a divider circuit (e.g., the divider circuit 150 in FIGS. 1 and 2) configured to receive the output signal and provide divider results (e.g., the divider results 153 in FIGS. 1 and 2) based on the output signal, where the temperature compensation circuit is configured to determine the group-delay amplitude based on the divider results. In some example embodiments, the temperature compensation circuit includes an amplitude modulation circuit (e.g., the AM circuit 154 in FIG. 1, or related components in FIG. 2) configured to: provide a mixed signal (e.g., the first mixer results 206 in FIG. 2) based on the output signal and the divider results; and provide modulation results (e.g., the modulation results 161 in FIGS. 1 and 2) based on the output signal and the mixed signal. In such example embodiments, the temperature compensation circuit is configured to determine the group-delay amplitude and the phase-delay sign based on the modulation results.

In some example embodiments, the temperature compensation circuit includes a mixer circuit (e.g., the second mixer circuit 220 in FIG. 2), a filter circuit (e.g., the filter circuit 224 in FIG. 2), and a TDC circuit (e.g., the TDC circuit 228 in FIG. 2). In such example embodiments, the mixer circuit is configured to provide a second mixed signal (e.g., the second mixer results 222 in FIG. 2) based on the output signal and delayed modulation results based on the second resonator, the filter circuit is configured to provide filter results 226 based on the second mixed signal, and the TDC circuit is configured to provide the group-delay amplitude responsive to the filter results and the divider results. In some example embodiments, the first resonator has second-order frequency variation as a function of temperature, and the second resonator has first-order frequency variation as a function of temperature. In some example embodiments, the oscillator control circuitry includes a TIA (e.g., the TIA 202 in FIG. 2), where the first resonator is part of a feedback loop of the TIA.

In some example embodiments, the first resonator 114 has first-order frequency variation as a function of temperature (i.e., Δf₁∝TCF₁·ΔT, where Δf₁ is the change in frequency of the first resonator 114, TCF₁ is the temperature coefficient of frequency of the first resonator 114, and ΔT is the change in temperature. In some example embodiments, the second resonator 134 has second-order frequency variation as a function of temperature (i.e., Δf₂∝TCF₂·ΔT², where Δf₂ is the change in frequency of the second resonator 134, TCF₂ is the temperature coefficient of frequency of the second resonator 134, and ΔT is the change in temperature.

In some example embodiments, the resonator group-delay analyzer 120A is configured to: apply a first offset to the group-delay amplitude 112 responsive to a positive sign being detected by the positive signal detect circuit; and apply a second offset to the group-delay amplitude 112 responsive to a negative sign being detected by the negative signal detect circuit, wherein the second offset is greater than the first offset.

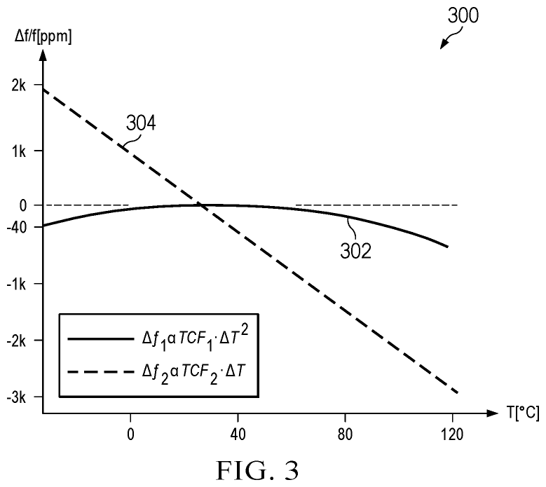

FIG. 3 is a graph 300 showing frequency variation as a function of temperature for a first and second resonators in accordance with an example embodiment. As shown in graph 300, the first resonator (e.g., the first resonator 114 in FIGS. 1 and 2) has second-order frequency variation 302 (e.g., Δf₁∝TCF₁·ΔT², where f₁ is the resonant frequency of the first resonator, TCF₁ is the temperature coefficient of frequency of the first resonator, and T is temperature) as a function of temperature. In other words, the frequency variation 302 of the first resonator is curved as a function of temperature. In contrast, the second resonator (e.g., the second resonator 134 in FIGS. 1 and 2) has first-order frequency variation 304 (Δf₂∝TCF₂·ΔT, where f₂ is the resonant frequency of the second resonator and TCF₂ is the temperature coefficient of frequency of the second resonator) as a function of temperature. In other words, the frequency variation of the second resonator is linear as a function of temperature. In some example embodiments, the first resonator is designed to have low frequency variation (near zero) for some temperatures. The intersection of the frequency variances 302 and 304 determines the accuracy of the temperature compensation. In different example embodiments, the frequency variation 302 of the first resonator and/or the frequency variation 304 of the second resonator may vary from the example of FIG. 3 but should have an intersection point near zero of the frequency variation curve of the second resonator to optimize accuracy of temperature compensation.

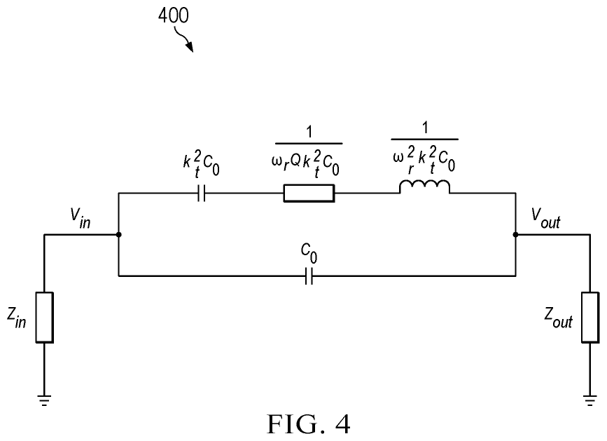

FIG. 4 is schematic diagram showing an equivalent circuit 400 related to a 2-port electroacoustic resonator (e.g., the first resonator 114 and/or the second resonator 134 may be an electroacoustic resonator) in accordance with an example embodiment. As shown, the equivalent circuit 400 includes parallel circuit with two branches between an input impedance (Zᵢₙ) and an output impedance (Zₒᵤₜ). The first branch of the parallel circuit include a first capacitor (with impedance kₜ²C₀, where kₜ is electromechanical coupling), a resistor (with impedance

$$\frac{1}{{ω}_{r} {Qk}_{t}^{2} {C}_{0}} ,$$

where wᵣ is me resonance frequency, and Q is the quality factor), and an inductor (with impedance

$$\frac{1}{{w}_{r} {k}_{t}^{2} {C}_{0}} ) .$$

The second branch of the parallel circuit includes a second capacitor C₀. If

$${Z}_{out} = \frac{1}{{sC}_{0}} ,$$

then

$$\frac{{V}_{out}}{{V}_{in}} ( s ) = \frac{\frac{{s}^{2}}{{w}_{r}^{2}} + \frac{s}{{w}_{r} Q} + ( q + {k}_{t}^{2} )}{\frac{{s}^{2}}{{w}_{r}^{2}} + \frac{s}{{w}_{r} Q} + ( 2 + {k}_{t}^{2} )} ,$$

where s is the complex variable of the Laplace transform.

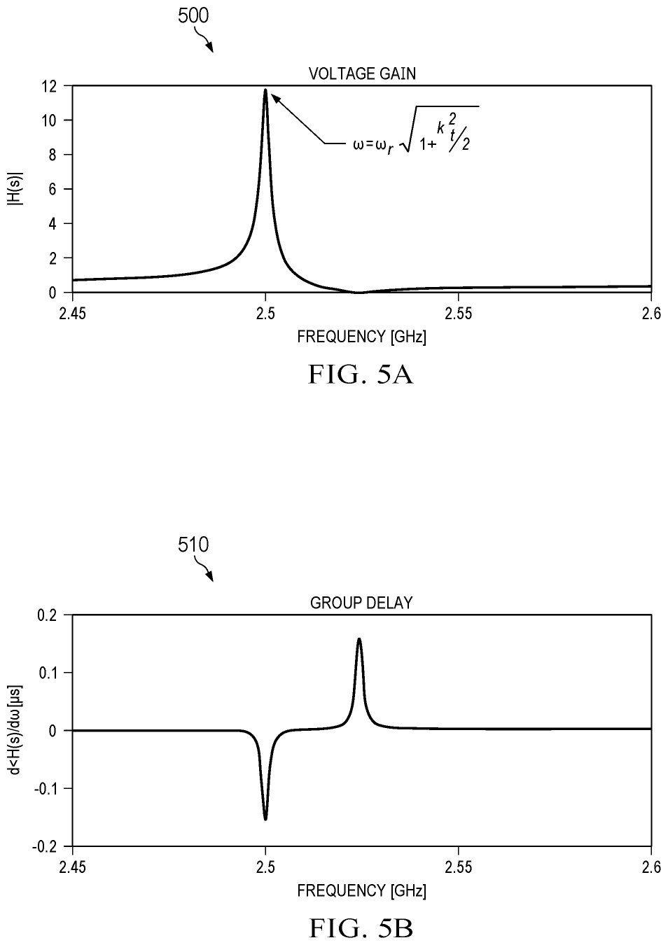

With the equivalent circuit 400, voltage gain of a resonator will have a peak as shown in graph 500 of FIG. 5A. FIGS. 5A and 5B are graphs 500 and 510 showing resonator frequency response in accordance with an example embodiment. In graph 500 of FIG. 5A, voltage gain as a function of frequency is shown for a resonator (e.g., the second resonator 134 used for temperature compensation). As shown in graph 500, the voltage gain as a function of frequency has a peak given as

$$ω = {ω}_{r} \sqrt{1 + {k}_{t}^{2} / 2} ,$$

where ω is the angular frequency. In graph 510 of FIG. 5B, group-delay as a function of frequency is shown for a resonator (e.g., the second resonator 134 used for temperature compensation). As shown, the group-delay has a negative peak and a positive peak. For graphs 500 and 510, example values of ωᵣ=2.4754 GHz, Q=1000, kₜ²=4%, and C₀=2 pF were assumed.

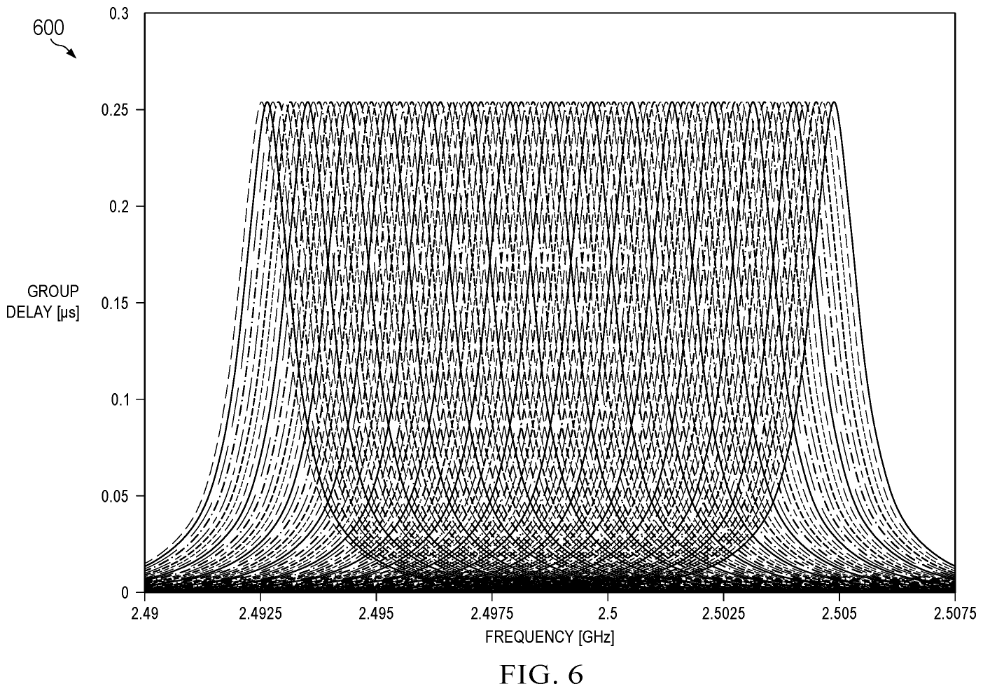

FIG. 6 is a graph 600 showing group-delay of an uncompensated resonator measured for different temperatures at a range of oscillator frequencies (f₀) from 2.49 GHz to 2.5075 GHz. As shown in graph 600, temperature variation results in a range of group-delays. With a range of group-delays as in graph 600, group-delay frequency can be correlated with a particular temperature and/or a group-delay frequency shift can be correlated with a temperature shift.

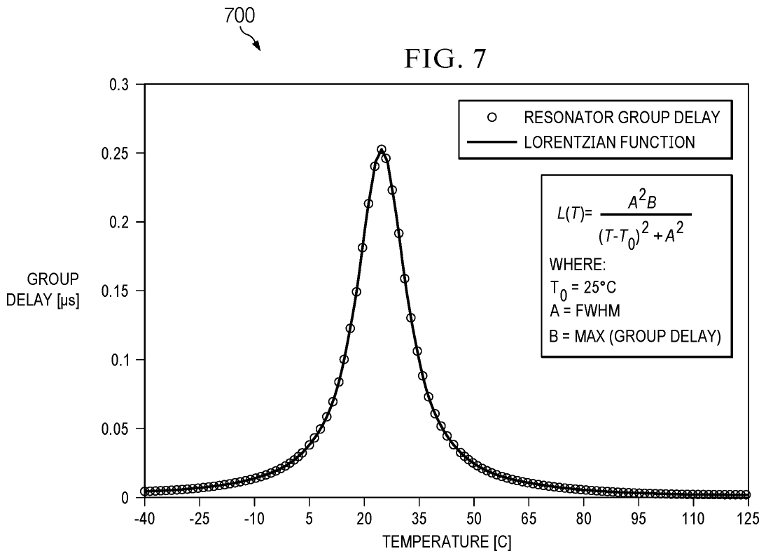

FIG. 7 is a graph 700 showing group-delay as a function of temperature. The graph 700 is based on a Lorentzian function applied to the group-delays of graph 600 that are detected when the oscillator frequency is fixed at 2.5 GHz. The Lorentzian function is given as:

$$L ( T ) = \frac{{FWHM}^{2} {L}_{c}}{4 {( T - {T}_{0} )}^{2} + {ω}^{2}} ,$$

where FWHM is full-width at half-maximum, L_{c} is the maximum group-delay, T is temperature, and T₀ is a setpoint temperature (e.g., 25° C.). In some example embodiments, a controller (e.g., the controller 129 in FIGS. 1 and 2) is configured to perform a temperature estimation based on a group-delay amplitude (e.g., the group-delay amplitude 112 in FIGS. 1 and 2) received from a resonator group-delay analyzer (e.g., the resonator group-delay analyzer 120 in FIG. 1, or related components in FIG. 2). Once the temperature has been estimated from the group-delay amplitude, the controller is configured to provide a control signal (e.g., the control signal 133) to oscillator control circuitry (e.g., the oscillator control circuitry 140 in FIG. 1, or the oscillator control circuitry 140A in FIG. 2) as described herein.

In some example embodiments, the group-delay amplitude is asymmetric as a function of temperature. To account for such asymmetry, the phase-delay sign may be used to determine which of multiple offsets to apply to the group-delay amplitude. In some example embodiments, a first offset may be applied by updating the Lorentzian function as follows:

$$L ( T ) = \frac{{ω}^{2} ( {L}_{c} + {L}_{1} )}{4 {( T - {T}_{0} )}^{2} + {ω}^{2}} - {L}_{1} ,$$

where L₁ is the first offset. Similarly, a second offset may be applied by updating the Lorentzian function as follows:

$$L ( T ) = \frac{{ω}^{2} ( {L}_{c} + {L}_{2} )}{4 {( T - {T}_{0} )}^{2} + {ω}^{2}} - {L}_{2} ,$$

where L₂ is the second offset. Without limitation, an example value for L₁ may be −2·10⁻¹⁰, and an example value for L₂ may be −5.1·10⁻¹⁰. In some example embodiments, a controller (e.g., the controller 129 in FIGS. 1 and 2) is configured to: modify the group-delay amplitude by applying a first offset (e.g., L₁) responsive to the phase-delay sign being positive; modify the group-delay amplitude by applying a second offset (e.g., L₂) to the group-delay amplitude responsive to the phase-delay sign being negative, where the second offset is greater than the first offset; and provide the control signal (e.g., the control signal 133 in FIGS. 1 and 2) based on the modified group-delay amplitude.

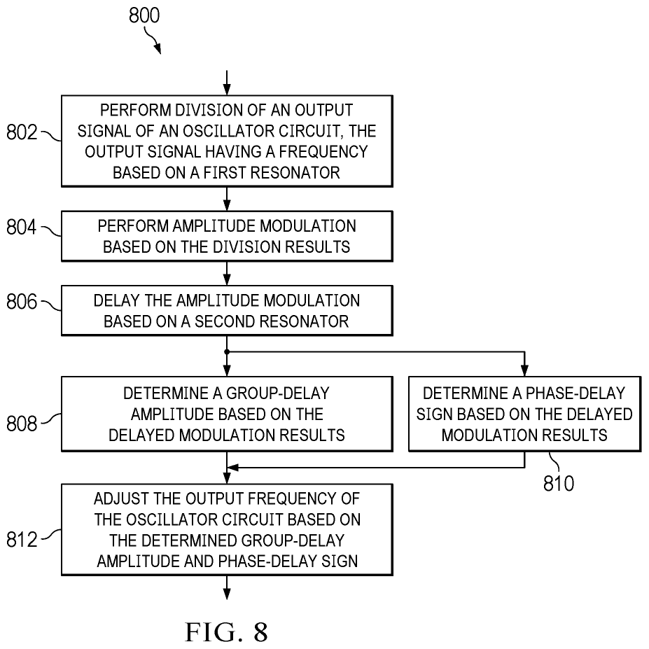

FIG. 8 is a flowchart showing an output frequency control method 800 for an oscillator circuit (e.g., the oscillator circuit 108 in FIG. 1, or the oscillator circuit 108A in FIG. 2) in accordance with an example embodiment. As shown, the method 800 includes performing a division of an output signal (e.g., CLK_OSC) of the oscillator circuit, the output signal having a frequency based on a first resonator, at block 802. At block 804, amplitude modulation is performed based on the division results (e.g., the divider results 153 in FIGS. 1 and 2). In some example embodiments, the amplitude modulation of block 804 involves summing the output frequency (e.g., CLK_OSC in FIGS. 1 and 2) of the oscillator circuit with mixer results (e.g., the first mixer results 206), which are based on the output frequency of the oscillator circuit and the division results from block 802. At block 806, the modulation results of block 804 (e.g., the modulation results 161 in FIGS. 1 and 2) are delayed based on a second resonator (e.g., the second resonator 134 in FIGS. 1 and 2). At block 808, a group-delay amplitude is determined based on the delayed modulation results obtained from block 806. The operations of block 808 may also be based on the modulation results from block 804 or the division results from block 802. At block 810, a phase-delay sign is determined based on the delayed modulation results from block 806. The operations of block 810 may also be based on the output frequency (e.g., CLK_OSC in FIGS. 1 and 2) of the oscillator circuit or the modulation results from block 804. At block 812, the output frequency of the oscillator circuit is adjusted based on the group-delay amplitude determined at block 808 and the phase-delay sign determined at block 810. In some example embodiments, the operations of block 812 involve: estimating a temperature or temperature shift based on the determined group-delay amplitude and phase-delay sign; generating a control signal based on the estimated temperature or temperature shift; and using the control signal to adjust the output frequency of the oscillator circuit.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter.

Modifications are possible in the described embodiments, and other embodiments are possible, within the scope of the claims.

What is claimed is:

1. A circuit, comprising:
a first resonator having first and second terminals;
a temperature compensation circuit including a resonator group-delay analyzer and a second resonator, the resonator group-delay analyzer having first and second analyzer inputs and an analyzer output, the second resonator having third and fourth terminals, the fourth terminal coupled to the first analyzer input;
oscillator control circuitry having a first control input, first and second outputs, and an oscillator output, the first output coupled to the first terminal, and the second output coupled to the second terminal; and
a controller having a second control input and a control output, the second control input coupled to the analyzer output, and the control output coupled to first control input, in which the controller is configured to provide a control signal at the control output responsive to a group-delay parameter received at the second control input, and the oscillator control circuitry is configured to adjust a frequency of an output signal at the oscillator output responsive to the control signal.

2. The circuit of claim 1, further comprising a divider circuit having a divider input and a divider output, the divider input coupled to the oscillator output, wherein the temperature compensation circuit includes an amplitude modulation circuit having a modulation output and first and second modulation inputs, the first modulation input coupled to the divider output, the second modulation input coupled to the oscillator output, the modulation output coupled to the third terminal, and the second analyzer input coupled to the modulation output or the divider output.

3. The circuit of claim 2, wherein the amplitude modulation circuit includes a summation circuit and a mixer circuit, the mixer circuit configured to provide mixer results based on the output signal and divider results at the divider output, and the summation circuit configured to provide modulation results based on the mixer results and the output signal.

4. The circuit of claim 3, wherein the mixer circuit is a first mixer circuit, the mixer results are first mixer results, and the resonator group-delay analyzer includes:
a second mixer circuit configured to provide second mixer results based on the output signal and delayed modulation results based on the second resonator,
a filter circuit configured to provide filter results responsive to the second mixer results; and
a time-to-digital converter (TDC) configured to provide the group-delay parameter responsive to the filter results and the divider results.

5. The circuit of claim 4, wherein the resonator group-delay analyzer includes an amplifier circuit between the fourth terminal and the second mixer circuit.

6. The circuit of claim 2, wherein the temperature compensation circuit includes a resonator phase-delay sign circuit having a sign circuit output and first and second sign circuit inputs, the first sign circuit input coupled to the fourth terminal, the second sign circuit input coupled to the modulation output or the oscillator output.

7. The circuit of claim 6, wherein the controller includes a third control input coupled to the sign circuit output, the controller configured to provide the control signal at the control output responsive to the group-delay parameter received at the second control input and a phase-delay sign received at the third control input.

8. The circuit of claim 7, wherein the group-delay parameter is a group-delay amplitude and the controller is configured to:
determine a temperature based on the group-delay amplitude and the phase-delay sign; and
provide the control signal responsive to the determined temperature.

9. The circuit of claim 8, wherein the controller is configured to determine the temperature based on a Lorentzian function having coefficients that vary as a function of a maximum group-delay amplitude, a full-width half maximum of the group-delay amplitude, the phase-delay sign, and a setpoint temperature.

10. The circuit of claim 6, wherein the resonator phase-delay sign circuit includes a D flip-flop having a D input, a reset input, a flip-flop output, the D input coupled to the first sign circuit input, the reset input coupled to the second sign circuit input, the flip-flop output coupled to the sign circuit output, and the D flip-flop configured to:
receive a first sign signal at the D input responsive to delayed modulation results based on the second resonator;
receive a second sign signal at the reset input responsive to the modulation results; and
provide a phase-delay sign at the flip-flop output responsive to the first and second sign signals.

11. The circuit of claim 1, wherein the first resonator has second-order frequency variation as a function of temperature, and second resonator has first-order frequency variation as a function of temperature.

12. An oscillator circuit, comprising:
a first resonator;
a temperature compensation circuit including a second resonator, the temperature compensation circuit configured to determine a group-delay amplitude responsive to operations of the second resonator;
oscillator control circuitry coupled to the first resonator and configured to adjust a frequency of an output signal of the oscillator circuit responsive to a control signal; and
a controller coupled to the oscillator control circuitry and the temperature compensation circuit, the controller configured to:
receive the group-delay amplitude from the temperature compensation circuit; and
provide the control signal to the oscillator control circuitry responsive to the group-delay amplitude.

13. The oscillator circuit of claim 12, wherein the temperature compensation circuit is configured to determine a phase-delay sign responsive to delayed modulation results based on the second resonator.

14. The oscillator circuit of claim 13, wherein the controller is configured to:
determine a temperature based on the group-delay amplitude and the phase-delay sign; and
provide the control signal responsive to the determined temperature.

15. The oscillator circuit of claim 14, wherein the controller is configured to determine the temperature based on a Lorentzian function having coefficients that vary as a function of a maximum group-delay amplitude, a full-width half maximum of the group-delay amplitude, the phase-delay sign, and a setpoint temperature.

16. The oscillator circuit of claim 12, further comprising a divider circuit configured to receive the output signal and provide a divider results based on the output signal, wherein the temperature compensation circuit is configured to determine the group-delay amplitude based on the divider results.

17. The oscillator circuit of claim 16, wherein the temperature compensation circuit includes an amplitude modulation circuit configured to:
provide mixer results based on the output signal and the divider results; and
provide modulation results based on the output signal and the mixer results, wherein the temperature compensation circuit is configured to determine the group-delay amplitude and a phase-delay sign based on the modulation results.

18. The oscillator circuit of claim 17, wherein the temperature compensation circuit includes a mixer circuit, a filter circuit, and a time-to-digital converter (TDC) circuit, the mixer results are first mixer results, the mixer circuit is configured to provide second mixer results based on the output signal and delayed modulation results based on the second resonator, the filter circuit is configured to provide filter results based on the second mixer results, and the TDC circuit is configured to provide the group-delay amplitude responsive to the filter results and the divider results.

19. The oscillator circuit of claim 12, wherein first resonator has second-order frequency variation as a function of temperature, and the second resonator has first-order frequency variation as a function of temperature.

20. The oscillator circuit of claim 12, wherein the oscillator control circuitry includes a transimpedance amplifier (TIA), wherein the first resonator is part of a feedback loop of the TIA.
